(19) United States
(12) Patent Application Publication
(10) Pub. No.: US 2021/0305155 A1
(43) Pub. Date: Sep. 30, 2021

(54) VIA ZERO INTERCONNECT LAYER METAL RESISTOR INTEGRATION

(71) Applicant: QUALCOMM Incorporated, San Diego, CA (US)

(72) Inventors: Junjing BAO, San Diego, CA (US); Giridhar NALLAPATI, San Diego, CA (US); Peijie FENG, San Diego, CA (US)

(21) Appl. No.: 16/834,618

(22) Filed: Mar. 30, 2020

(51) Int. Cl. H01L 23/522; H01L 21/768

(52) U.S. Cl. CPC H01L 23/5228; H01L 28/24; H01L 21/76816; H01L 23/5226

(57) ABSTRACT

An integrated circuit (IC) is described. The IC includes a substrate having an active device having an active region. The IC also includes a middle-of-line (MOL) interconnect layer having a contact merge (CM) layer on a trench contact coupled to the active region of the active device. The IC further includes back-end-of-line (BEOL) interconnect layers on the MOL interconnect layer. The IC also includes a metal resistor in a via zero interconnect layer between a first BEOL interconnect and the MOL interconnect layer. The metal resistor is coupled to the active region through a first via zero on the CM layer, a second via zero on the metal resistor, and the first BEOL interconnect on the first via zero and the second via zero.

### BACKGROUND

### Field

Aspects of the present disclosure relate to semiconductor devices and, more particularly, to a metal resistor integrated into a via zero interconnect layer.

### Background

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

The design of complex complementary metal oxide semiconductor (CMOS) system-on-chips (SoCs) may be affected by parasitic resistance and capacitance due to layer-to-layer interconnects. That is, dynamic performance of complex CMOS SoCs (e.g., an alternating current (AC) performance) may be detrimentally affected by parasitic resistance and capacitance generated by layer-to-layer interconnects. CMOS SoC circuit design techniques that address parasitic resistance and capacitance from layer-to-layer interconnections are desired.

### SUMMARY

An integrated circuit (IC) is described. The IC includes a substrate having an active device having an active region. The IC also includes a middle-of-line (MOL) interconnect layer having a contact merge (CM) layer on a trench contact coupled to the active region of the active device. The IC further includes back-end-of-line (BEOL) interconnect layers on the MOL interconnect layer. The IC also includes a metal resistor in a via zero interconnect layer between a first BEOL interconnect and the MOL interconnect layer. The metal resistor is coupled to the active region through a first via zero on the CM layer, a second via zero on the metal resistor, and the first BEOL interconnect on the first via zero and the second via zero.

A method for integrating a metal resistor into a via zero interconnect layer is described. The method includes forming, in a middle-of-line (MOL) interconnect layer, a contact merge (CM) layer to land on a trench contact, coupled to an active region of a substrate. The method also includes forming, in the via zero interconnect layer, the metal resistor. The method further includes forming, in the via zero interconnect layer, a first via zero to land on the CM layer and a second via zero to land on the metal resistor. The method further includes fabricating, in a first back-end-of-line (BEOL) interconnect layer, a first BEOL interconnect on the via zero interconnect layer, the first via zero, and the second via zero configured to couple the metal resistor to the active region.

An integrated circuit (IC) is described. The IC includes a substrate including an active device having an active region. The IC also includes a middle-of-line (MOL) interconnect layer having a contact merge (CM) layer on a trench contact coupled to the active region of the active device. The IC further includes back-end-of-line (BEOL) interconnect layers on the MOL interconnect layer. The IC also includes means for improving alternating current (AC) performance of the IC in a via zero interconnect layer between a first BEOL interconnect and the MOL interconnect layer. The AC performance improving means coupled to the active region through a first via zero on the CM layer, a second via zero on the AC performance improving means, and the first BEOL interconnect on the first via zero and the second via zero.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a system-on-chip (SoC), including a via zero interconnect layer metal resistor, in accordance with certain aspects of the present disclosure.

FIG. 2 is a cross-section illustrating an integrated circuit (IC) device including an interconnect stack of back-end-of-line (BEOL) layers.

FIG. 3 illustrates a side view of an integrated circuit device including a front-end-of-line (FEOL) layer, a middle-of-line (MOL) interconnect layer, and a via zero interconnect layer.

FIG. 4 shows a cross-sectional view illustrating an integrated circuit (IC) device, having a via zero interconnect layer metal resistor integration, according to aspects of the present disclosure.

FIGS. 5A-5D are cross-sections illustrating a process to fabricate the integrated circuit (IC) device of FIG. 4, according to aspects of the present disclosure.

FIG. 6 is a process flow diagram illustrating a method for integrating a metal resistor into a via zero interconnect layer, according to an aspect of the present disclosure.

FIG. 7 is a block diagram showing an exemplary wireless communications system in which a configuration of the disclosure may be advantageously employed.

FIG. 8 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

A system hierarchy includes interconnection of active devices at a lowest system level all the way up to system level interconnections at a highest level. Electrical connections exist at each of the levels of the system hierarchy to connect different devices together on an integrated circuit. As integrated circuits become more complex, however, more interconnect layers are used to provide the electrical connections between the devices. More recently, the number of interconnect levels for circuitry has substantially increased due to the large number of devices that are now interconnected in a modern electronic device.

These interconnections include back-end-of-line (BEOL) interconnect layers, which may refer to the conductive interconnect layers (e.g., a first BEOL interconnect layer or metal one (M1), metal two (M2), metal three (M3), metal four (M4), etc.) for electrically coupling to front-end-of-line active devices of an integrated circuit. The various back-end-of-line interconnect layers are formed at corresponding back-end-of-line interconnect levels, in which lower back-end-of-line interconnect levels use thinner metal layers relative to upper back-end-of-line interconnect levels. The back-end-of-line interconnect layers may electrically couple to middle-of-line interconnect layers, for example, to connect M1 to an oxide diffusion (OD) layer of an integrated circuit. A via zero interconnect layer may connect M1 to an active device layer of an integrated circuit through trench contacts and a contact merge (CM) layer.

For example, in an integrated circuit (IC) device a CM layer provides a vertical connection to trench contacts CA to contact the active devices (e.g., N-type/P-type diffusion regions) within a front-end-of-line (FEOL) layer without exceeding a minimal standard cell size. Unfortunately, the CM layer generates parasitic resistance and capacitance, which degrades an alternating current (AC) performance (e.g., >4%) of the IC device. To improve the AC performance of the IC device, a metal resistor may be built within a middle of the MOL interconnect layer proximate to a CM layer. For example, a CM layer lands on the metal resistor for connection to the active devices of the IC device.

Various aspects of the disclosure provide a via zero interconnect layer metal resistor. A process flow for fabrication of a via zero interconnect layer metal resistor may include front-end-of-line (FEOL) processes, middle-of-line (MOL) processes, and back-end-of-line (BEOL) processes. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. Similarly, the terms “chip” and “die” may be used interchangeably. In addition the terms resistor metal (RM) and metal resistor may be used interchangeably.

According to aspects of the present disclosure, an alternating current (AC) performance of a CMOS device is improved by fabricating a metal resistor in the via zero interconnect layer rather than an MOL interconnect layer. Relocation of the metal resistor from the MOL interconnect layer enables a height reduction of the MOL interconnect layer, which includes a contact merge layer. According to this aspect of the present disclosure, a height of the contact merge layer is substantially reduced (e.g., by 50%). The height reduction of the contact merge layer (and the MOL interconnect layer) substantially reduces the parasitic resistance and capacitance caused by the contact merge layer. This substantial reduction in the parasitic resistance and capacitance associated with the contact merge layer (and the MOL interconnect layer) also improves the AC performance of the CMOS device (e.g., >2%).

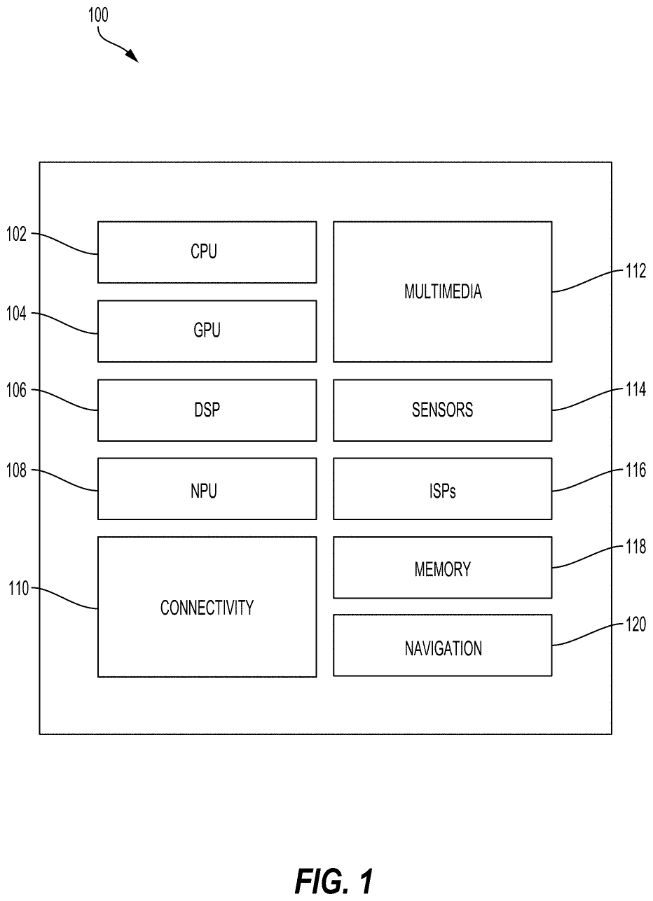

FIG. 1 illustrates an example implementation of a host system-on-chip (SoC) 100, which includes a via zero interconnect layer metal resistor, in accordance with aspects of the present disclosure. The host SoC 100 includes processing blocks tailored to specific functions, such as a connectivity block 110. The connectivity block 110 may include fifth generation (5G) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU 108, and the multimedia engine 112 support various functions such as video, audio, graphics, gaming, artificial networks, and the like. Each processor core of the multi-core CPU 102 may be a reduced instruction set computing (RISC) machine, an advanced RISC machine (ARM), a microprocessor, or some other type of processor. The NPU 108 may be based on an ARM instruction set.

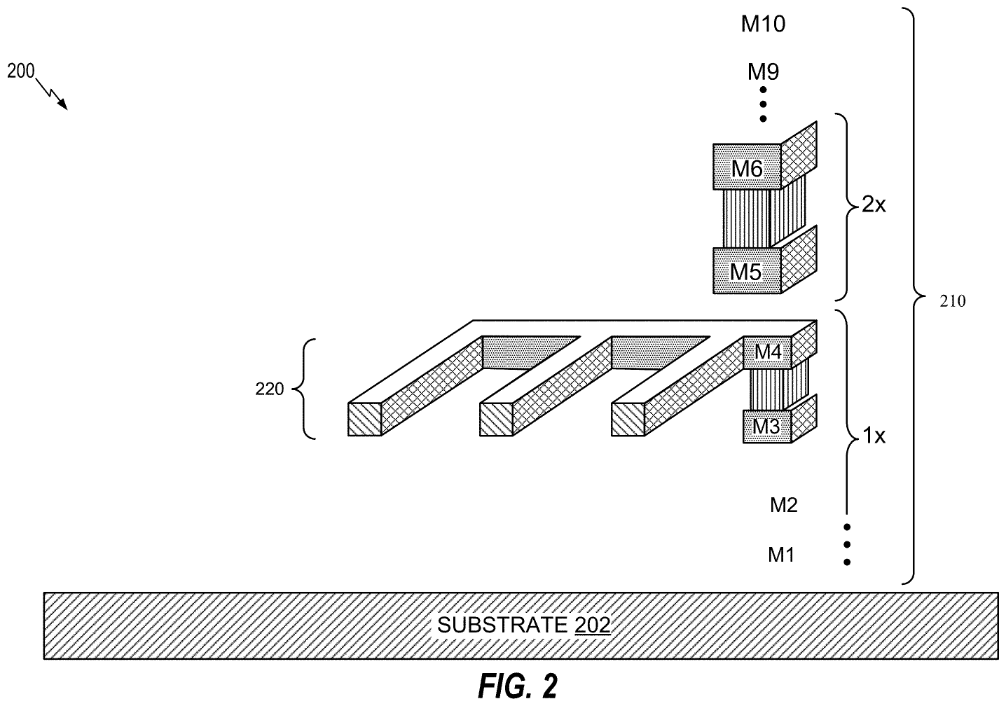

FIG. 2 is a block diagram illustrating a cross-section of an integrated circuit (IC) device 200 including an interconnect stack 210. The interconnect stack 210 of the IC device 200 includes multiple back-end-of-line (BEOL) conductive interconnect layers (M1, . . . , M9, M10) on a semiconductor substrate 202 (e.g., a diced silicon wafer). The semiconductor substrate 202 may be fabricated to include an active device layer (not shown) using complementary metal oxide semiconductor (CMOS) technology. The various BEOL interconnect layers are formed at corresponding BEOL interconnect levels, in which lower BEOL interconnect levels (e.g., M1) use thinner metal layers relative to upper (e.g., M9) BEOL interconnect levels. In this example, an interconnect structure 220 is formed at an M4 interconnect layer, between M3 and M5 interconnect layers.

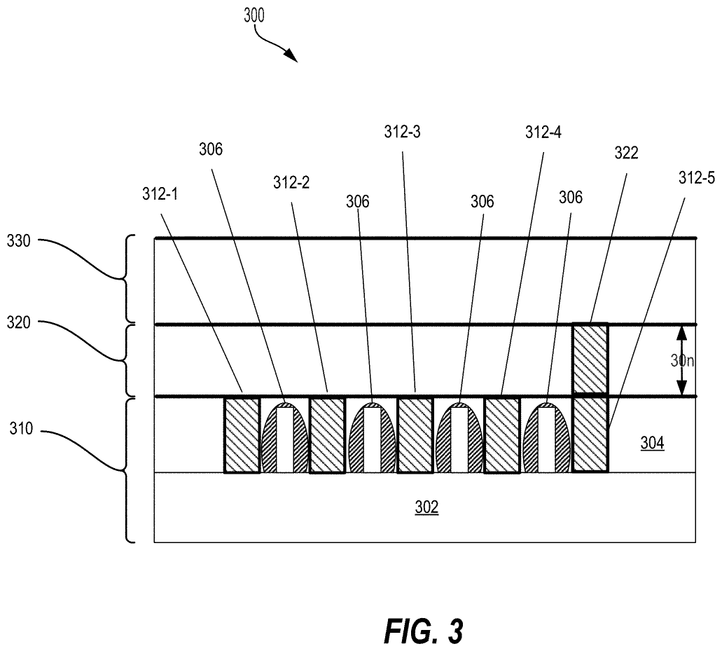

FIG. 3 shows a cross-sectional view illustrating an integrated circuit (IC) device 300, showing a front-end-of-line (FEOL) layer 310, a middle of line (MOL) interconnect layer 320, and a via zero interconnect layer 330. The IC device 300 includes a semiconductor substrate (e.g., a silicon wafer) 302 having shallow trench isolation (STI) regions 304 (e.g., an isolation layer). Within the FEOL layer 310 (including the substrate 302) is an active region (e.g., well region or source/drain region) in which active devices having a source region, a drain region, and a gate region (e.g., conductive gate 306) are formed. This region, including the substrate 302 may be collectively referred to as the FEOL layer 310. The IC device 300 may be a complementary metal oxide semiconductor (CMOS) transistor.

In FIG. 3, the FEOL layer 310 includes a set of active (oxide diffusion (OD)) contacts, which are often referred to as metal diffusion trench contacts, shown as trench contacts 312-1, 312-2, 312, 3, 312-4, and 312-5 (collectively or generally referred to as trench contacts 312). The trench contacts 312 are fabricated on the substrate 302 to contact oxide diffusion regions (not shown) of the substrate 302. For example, the trench contacts 312 may be coupled to the active devices (e.g., the source and drain regions) within the FEOL layer 310. The MOL interconnect layer 320 provides interconnection to the trench contacts 312 within the FEOL layer 310.

In one configuration, the MOL interconnect layer 320 provides a stacked trench contact, which is referred to as a contact merge (CM) layer 322, for interconnection to the trench contact 312-5. The CM layer 322 interconnects to, for example, the BEOL conductive interconnect layers (M1, . . . , M9, M10) of FIG. 2. Interconnection to these BEOL conductive interconnect layers (M1, . . . , M9, M10) is provided through the via zero interconnect layer 330. As described herein, the via zero interconnect layer 330 refers to an interconnect transition region between the MOL interconnect layer 320 and the first BEOL interconnect layer of the BEOL conductive interconnect layers (M1, . . . , M9, M10) FIG. 2. The MOL interconnect layer 320 and the via zero interconnect layer 330 may be composed of tungsten or other like conductive material.

In this example, the CM layer 322 provides a vertical connection to contact the active devices (e.g., N-type/P-type diffusion regions) within the FEOL layer 310 without exceeding a minimal standard cell size. Unfortunately, the CM layer 322 generates parasitic resistance and capacitance, which degrades an alternating current (AC) performance (e.g., >4%) of the IC device 300. To improve the AC performance of the IC device 300, a metal resistor (e.g., TiN, TaN, WN) in a resistor metal (RM) layer is conventionally built in the middle of the MOL interconnect layer 320 proximate to the CM layer 322. For example, a reduced height CM′ layer lands on the metal resistor for connection to the active devices of the FEOL layer 310.

In order to prevent over-etch of the reduced height CM′ layer into the resistor metal (RM) layer (e.g., a short to the trench contacts 312, PC (poly contact(s) to conductive gate 306 underneath) and chemical-mechanical-polish (CMP) over-polish (e.g., no CM layer landing on resistor metal RM layer), the CM layer 322 is maintained at an increased height (e.g., 30 nanometers). When the CM layer 322 is fabricated at the increased height, a coupling capacitance to poly contacts of the conductive gate 306 is high and a resistance of the CM layer 322 is high.

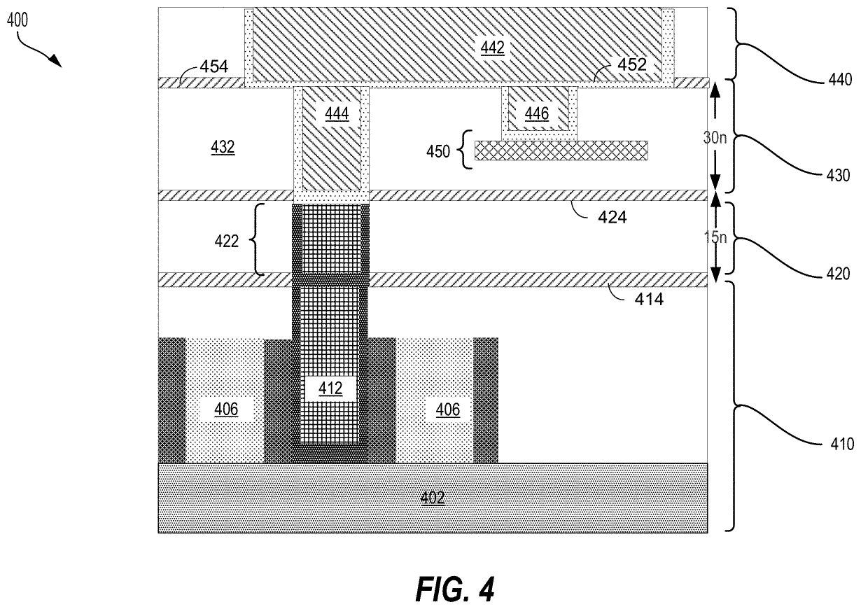

According to aspects of the present disclosure, an AC performance of a CMOS device is improved by fabricating a metal resistor in the via zero interconnect layer 330 rather than an MOL interconnect layer 320. According to this aspect of the present disclosure, a height of a contact merge layer is substantially reduced (e.g., by 50%). The substantial height reduction of the CM layer 322 substantially reduces the parasitic resistance and capacitance due to the CM layer 322. This substantial reduction in the parasitic resistance and capacitance associated with the CM layer 322 also improves the AC performance of the CMOS device (e.g., >2%), for example, as shown in FIG. 4.

FIG. 4 shows a cross-sectional view illustrating an integrated circuit (IC) device 400, having a via zero interconnect layer metal resistor integration, according to aspects of the present disclosure. The IC device 400 includes a front-end-of-line (FEOL) layer 410, a middle of line (MOL) interconnect layer 420, a via zero interconnect layer 430, and a first BEOL interconnect layer 440. The IC device 400 includes a semiconductor substrate (e.g., a silicon wafer) 402. Similar to the description in FIG. 3, an active region is within the FEOL layer 410 (including the substrate 402), in which active devices having a source region, a drain region, and a gate region (e.g., conductive gate 406) are formed. A first etch stop layer 414 (e.g., silicon nitride (SiN)) is also shown on the FEOL layer 410.

In FIG. 4, the FEOL layer 410 includes a trench contact 412. The trench contact 412 is fabricated on the substrate 402 to contact oxide diffusion regions (not shown) of the substrate 402. The trench contact 412 is coupled to the active devices (e.g., the source and drain regions) within the FEOL layer 410. The MOL interconnect layer 420 provides interconnection to the trench contact 412 within the FEOL layer 410. In one configuration, the MOL interconnect layer 420 provides a contact merge (CM) layer 422 for interconnection to the trench contact 412. A second etch stop layer 424 (e.g., aluminum nitride (AlN)/oxygen-doped silicon carbide (ODC)) is also shown on the MOL interconnect layer 420. The CM layer 422 and the trench contact 412 may be composed of one of tungsten (W), cobalt (Co), or ruthenium (Ru).

According to aspects of the present disclosure, the CM layer 422 interconnects to the via zero interconnect layer 430. The via zero interconnect layer 430 provides interconnection to, for example, the BEOL conductive interconnect layers (M1, . . . , M9, M10) of FIG. 2. That is, the via zero interconnect layer 430 is a transition interconnection layer between the BEOL conductive interconnect layers (M1, . . . , M9, M10) and the CM layer 422 of the MOL interconnect layer 420. In this example, the via zero interconnect layer 430 includes a dielectric layer 432. In addition, a third etch stop layer 454 (e.g., aluminum nitride (AlN)/oxygen-doped silicon carbide (ODC)) is also shown on the via zero interconnect layer 430.

As further illustrated in FIG. 4, a first via zero 444 of the via zero interconnect layer 430 couples the CM layer 422 to a first BEOL interconnect 442 of the first BEOL interconnect layer 440. In this aspect of the present disclosure, a second via zero 446 (e.g., reduced height via zero) lands on a metal resistor 450 for connection to the active devices of the FEOL layer 410. In this example, a height of the metal resistor 450 within the via zero interconnect layer 430 is fifteen nanometers (15 nm), and a thickness of the metal resistor 450 is five nanometers (5 nm). In addition, a height of the second via zero is ten (10) nanometers, such that a total height of the via zero interconnect layer is thirty (30) nanometers, which is greater than the thickness of the MOL interconnect layer 420 (e.g., 15 nanometers). The metal resistor 450 may be composed of one of titanium nitride (TiN), tantalum nitride (TaN), tungsten nitride (WN), or tungsten silicide (WSix).

According to aspects of the present disclosure, an AC performance of the IC device 400 is improved by fabricating the metal resistor 450 in the via zero interconnect layer 430 rather than the MOL interconnect layer 420. According to this aspect of the present disclosure, relocation of the metal resistor 450 to the via zero interconnect layer 430 enables a substantial reduction of the height of the CM layer 422 (e.g., by 50%) of the MOL interconnect layer 420. For example, in FIG. 3, the height of the CM layer 322 (e.g., 30 nanometers) is cut in half by the CM layer 422 in FIG. 4 (e.g., 15 nanometers), assuming a critical dimension of the CM layer 422 of twenty (20) nanometers. The substantial height reduction of the CM layer 422 substantially reduces the parasitic resistance and capacitance relative to the CM layer 322 in FIG. 3. This substantial reduction in the height of the CM layer 422 also improves the AC performance of the IC device 400 (e.g., >2%).

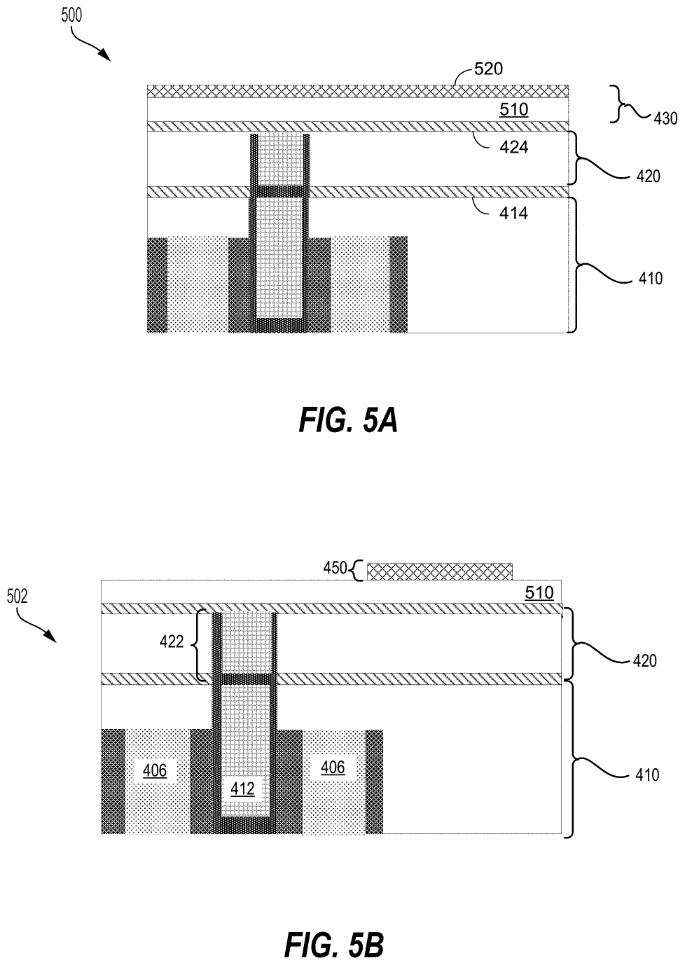

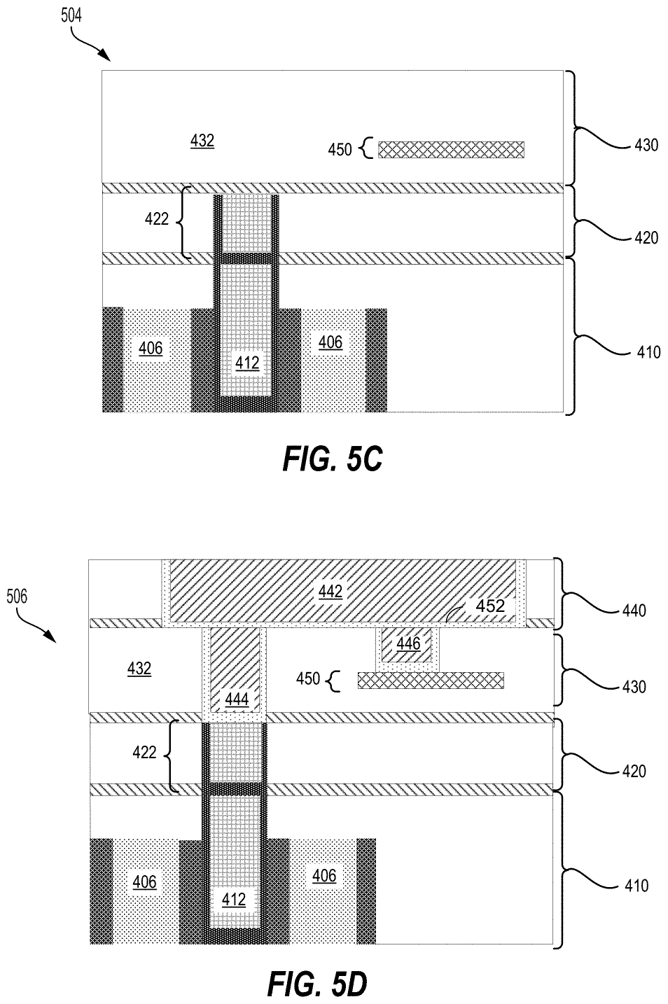

FIGS. 5A-5D are cross-sections illustrating a process to fabricate the integrated circuit (IC) device 400 of FIG. 4, according to aspects of the present disclosure. FIG. 5A, shows the IC device 400 of FIG. 4 after a step 500 of forming the FEOL layer 410 and the MOL interconnect layer 420. The step 500 also includes depositing the second etch stop layer 424 (e.g., aluminum nitride (AlN)/oxygen-doped silicon carbide (ODC)) on the MOL interconnect layer 420. Once formed, a partial dielectric layer 510 (e.g., a low-K silicon carbon oxygen hydrogen (SiCOH) layer) is formed on the second etch stop layer 424.

In this aspect of the present disclosure, a resistor metal (RM) layer 520 is deposited on the partial dielectric layer 510. In this example, the partial dielectric layer 510 is deposited to reach a height of fifteen (15) nanometers, to correspond with the configuration of the IC device 400 shown in FIG. 4. The resistor metal layer 520 may be composed of titanium nitride (TiN), tantalum nitride (TaN), tungsten nitride (WN), tungsten silicide (WSix), or other like conductive material. The resistor metal layer 520 is beneficially relocated from the MOL interconnect layer 420 to the via zero interconnect layer 430, as further illustrated in FIG. 5B.

FIG. 5B shows the IC device 400 of FIG. 4 after a step 502 of forming the metal resistor 450, according to aspects of the present disclosure. In this configuration, the resistor metal layer 520 of FIG. 5A is patterned and etched to form the metal resistor 450. For example, the resistor metal layer 520 is etched to expose the partial dielectric layer 510 and remove the resistor metal layer 520 from unwanted areas of the partial dielectric layer 510 to complete formation of the metal resistor 450.

FIG. 5C shows the IC device 400 of FIG. 4 after a step 504 of depositing an additional portion of the partial dielectric layer 510 to form the dielectric layer 432, according to aspects of the present disclosure. In this configuration, a BEOL low-K dielectric material is deposited on the partial dielectric layer 510 and the metal resistor 450. For example, BEOL low-K dielectric material, which is deposited on the partial dielectric layer 510 and the metal resistor 450, may be a low-K silicon carbon oxygen hydrogen (SiCOH) layer to complete the dielectric layer 432 of the via zero interconnect layer 430.

FIG. 5D shows the IC device 400 of FIG. 4 after a step 506 of forming the first BEOL interconnect layer 440, according to aspects of the present disclosure. In this example, the via zero interconnect layer 430 is patterned to define the first via zero 444 and the second via zero 446 within the dielectric layer 432. Once defined, a barrier layer 452 may be deposited in openings of the dielectric layer 432 defined to form the first via zero 444 and the second via zero 446. A single damascene process or a dual damascene process fills the openings in the dielectric layer 432 to form the first via zero 444 and the second via zero 446. Once formed, the first BEOL interconnect layer 440 is formed. In one configuration, the first via zero 444 of the via zero interconnect layer 430 couples the CM layer 422 to the first BEOL interconnect 442. In this configuration, the second via zero 446 (e.g., reduced height via zero) lands on the metal resistor 450 for connection to the active devices of the FEOL layer 410. A second BEOL interconnect layer may be formed on the first BEOL interconnect 442. The first BEOL interconnect 442, the first via zero 444 and the second via zero 446 may be composed of one of copper (Cu), cobalt (Co), ruthenium (Ru), or tungsten (W)

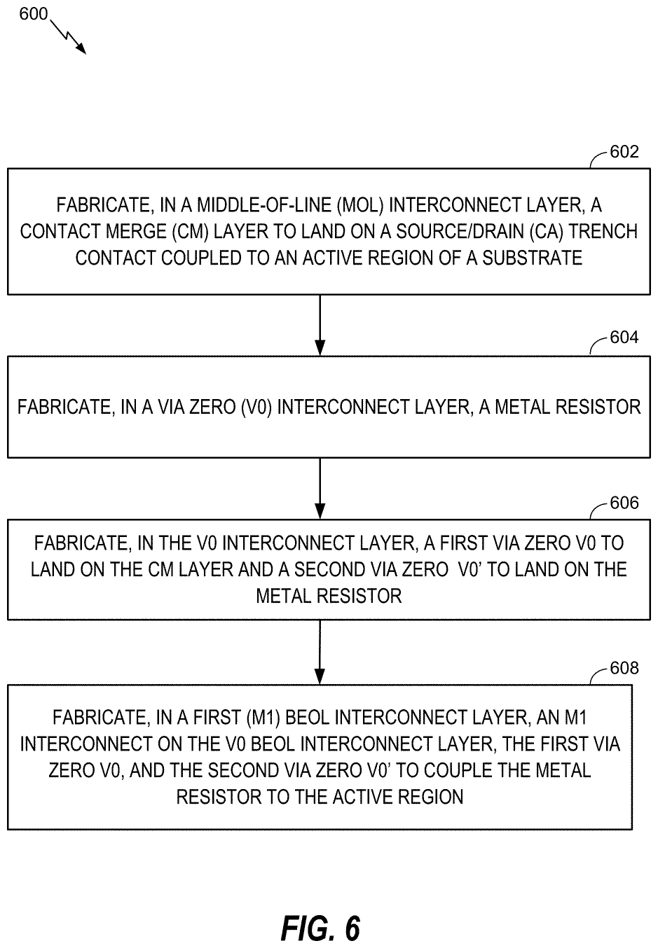

FIG. 6 is a process flow diagram illustrating a method for integrating a metal resistor into a via zero interconnect layer, according to an aspect of the present disclosure. A method 600 begins in block 602, in which a contact merge (CM) layer is fabricated in a middle-of-line (MOL) interconnect layer to land on a source/drain (CA) trench contact coupled to an active region of a substrate. For example, as shown FIG. 4, a contact merge layer 422 of the MOL interconnect layer 420 provides interconnection to the trench contact 412 within the FEOL layer 410. In this example, the MOL interconnect layer 420 includes the CM layer 422 for interconnection to the trench contact 412.

At block 604, the metal resistor is fabricated in the via zero interconnect layer. As shown in FIGS. 5A-5C, the resistor metal layer 520 of FIG. 5A is patterned and etched to form the metal resistor 450. For example, the resistor metal layer 520 is etched to expose the partial dielectric layer 510 and remove the resistor metal layer 520 from unwanted areas of the partial dielectric layer 510 to complete formation of the metal resistor 450. As shown in FIG. 5C, a BEOL low-K dielectric material is deposited on the partial dielectric layer 510 and the metal resistor 450 to complete the dielectric layer 432 of the via zero interconnect layer 430. For example, a BEOL low-K dielectric layer deposited on the partial dielectric layer 510 and the metal resistor 450 may be a low-K silicon carbon oxygen hydrogen (SiCOH) layer to complete the dielectric layer 432 of the via zero interconnect layer 430.

At block 606, a first via zero is fabricated to land on the CM layer and a second via zero is fabricated to land on the metal resistor are in the via zero interconnect layer. For example, as shown in FIG. 5D, the via zero interconnect layer 430 is patterned to define the first via zero 444 and the second via zero 446 within the dielectric layer 432. Once defined, a barrier layer 452 may be deposited in openings of the dielectric layer 432 to form the first via zero 444 and the second via zero 446. A single damascene process or a dual damascene process fills the openings in the dielectric layer 432 and forms the first via zero 444 and the second via zero 446.

At block 608, a first BEOL interconnect on the via zero interconnect layer is fabricated in a first BEOL interconnect layer and on the first via zero and the second via zero to couple the resistor metal RM to the active region. Once the first via zero 444 and the second via zero 446 are formed, the first BEOL interconnect layer 440 is formed, as seen in FIG. 5D. In this example, the first BEOL interconnect 442 couples the first via zero 444 to the second via zero of the via zero interconnect layer 430. In one configuration, the second via zero 446 (e.g., reduced height via zero) lands on the metal resistor 450 for connection to the active devices of the FEOL layer 410.

According to a further aspect of the present disclosure, a via zero interconnect layer integration is described. In one configuration, the IC includes means for improving alternating current (AC) performance of the IC. In one configuration, the AC performance improving means may be the metal resistor 450, as shown in FIG. 4, or the resistor metal layer 520, as shown in FIG. 5A. In another aspect, the aforementioned means may be any structure or any material configured to perform the functions recited by the aforementioned means. (Completed after claim language approval).

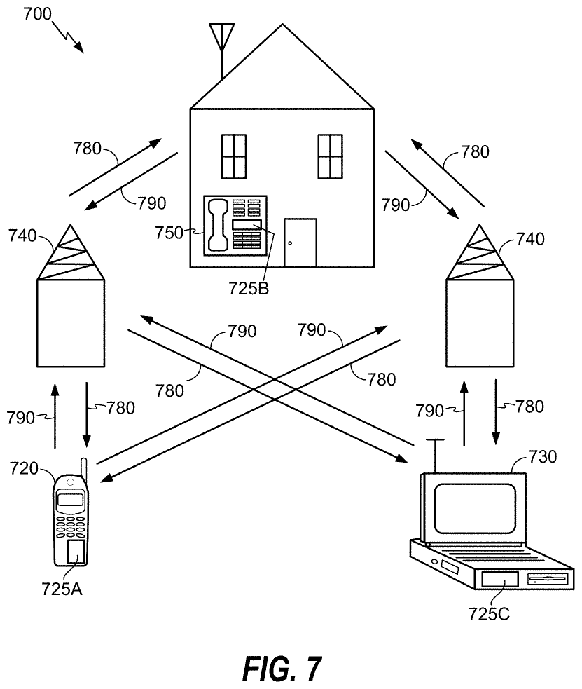

FIG. 7 is a block diagram showing an exemplary wireless communications system 700 in which an aspect of the disclosure may be advantageously employed. For purposes of illustration, FIG. 7 shows three remote units 720, 730, and 750, and two base stations 740. It will be recognized that wireless communications systems may have many more remote units and base stations. Remote units 720, 730, and 750 include IC devices 725A, 725C, and 725B that include the disclosed via zero interconnect layer metal resistor. It will be recognized that other devices may also include the disclosed via zero interconnect layer metal resistor, such as the base stations, switching devices, and network equipment. FIG. 7 shows forward link signals 780 from the base stations 740 to the remote units 720, 730, and 750, and reverse link signals 790 from the remote units 720, 730, and 750 to base stations 740.

In FIG. 7, remote unit 720 is shown as a mobile telephone, remote unit 730 is shown as a portable computer, and remote unit 750 is shown as a fixed location remote unit in a wireless local loop system. For example, the remote units may be a mobile phone, a hand-held personal communications systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 7 illustrates remote units according to aspects of the present disclosure, the disclosure is not limited to these exemplary illustrated units. Aspects of the present disclosure may be suitably employed in many devices, which include the disclosed via zero interconnect layer metal resistor.

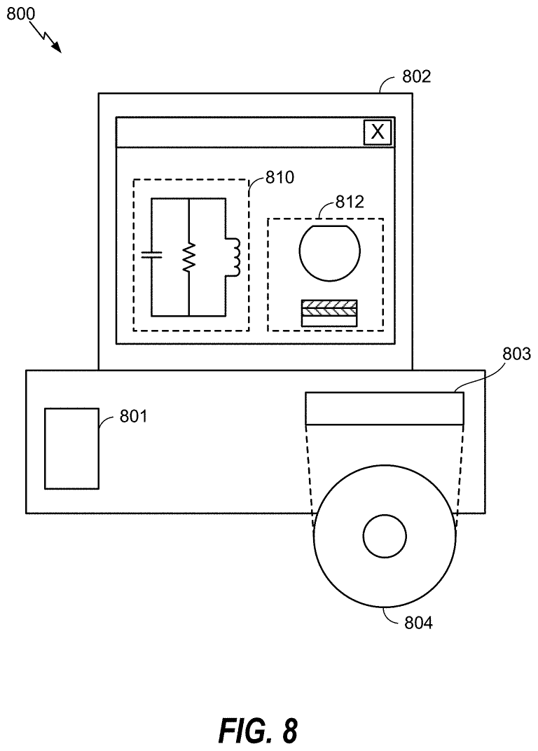

FIG. 8 is a block diagram illustrating a design workstation used for circuit, layout, and logic design of a semiconductor component, such as the capacitors disclosed above. A design workstation 800 includes a hard disk 801 containing operating system software, support files, and design software such as Cadence or OrCAD. The design workstation 800 also includes a display 802 to facilitate design of a circuit 810 or an integrated circuit (IC) component 812 such as a via zero interconnect layer metal resistor. A storage medium 804 is provided for tangibly storing the design of the circuit 810 or the IC component 812 (e.g., the via zero interconnect layer metal resistor). The design of the circuit 810 or the IC component 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit 810 or the IC component 812 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. An integrated circuit (IC), comprising:
a substrate including an active device having an active region;
a middle-of-line (MOL) interconnect layer having a contact merge (CM) layer on a trench contact coupled to the active region of the active device;
a plurality of back-end-of-line (BEOL) interconnect layers on the MOL interconnect layer; and
a metal resistor in a via zero interconnect layer between a first BEOL interconnect and the MOL interconnect layer, the metal resistor coupled to the active region through a first via zero on the CM layer, a second via zero on the metal resistor, and the first BEOL interconnect on the first via zero and the second via zero.

2. The IC of claim 1, in which a height of the first via zero is greater than a height of the second via zero.

3. The IC of claim 1, in which a height of the MOL interconnect layer is less than a height of the via zero interconnect layer.

4. The IC of claim 1, in which the via zero interconnect layer comprises a low-K dielectric material.

5. The IC of claim 1, further comprising:
a first etch stop layer between a front-end-of-line (FEOL) layer and the MOL interconnect layer; and
a second etch stop layer between the MOL interconnect layer and the via zero interconnect layer.

6. The IC of claim 1, in which the active device comprises a complementary metal oxide semiconductor (CMOS) transistor and the active region comprises a source/drain region.

7. The IC of claim 1, in which the metal resistor comprises one of titanium nitride (TiN), tantalum nitride (TaN), tungsten nitride (WN), or tungsten silicide (WSix).

8. The IC of claim 1, in which the first BEOL interconnect, the first via zero and the second via zero comprise one of copper (Cu), cobalt (Co), ruthenium (Ru), or tungsten (W).

9. The IC of claim 1, in which the CM layer and the trench contact comprise one of tungsten (W), cobalt (Co), or ruthenium (Ru).

10. A method for integrating a metal resistor into a via zero interconnect layer, comprising:
forming, in a middle-of-line (MOL) interconnect layer, a contact merge (CM) layer to land on a trench contact, coupled to an active region of a substrate;
forming, in the via zero interconnect layer, the metal resistor;
forming, in the via zero interconnect layer, a first via zero to land on the CM layer and a second via zero to land on the metal resistor; and
forming, in a first back-end-of-line (BEOL) interconnect layer, a first BEOL interconnect on the via zero interconnect layer, the first via zero, and the second via zero configured to couple the metal resistor to the active region.

11. The method of claim 10, further comprising:
forming a front-end-of-line (FEOL) layer having an active device including the active region of the substrate;
forming the MOL interconnect layer on the FEOL layer including the CM layer landing on the trench contact in the FEOL layer; and
forming the via zero interconnect layer on the MOL interconnect layer.

12. The method of claim 10, in which forming the metal resistor comprises:
depositing a first etch stop layer on the MOL interconnect layer;
depositing a dielectric material on the first etch stop layer to a predetermined height relative to the first etch stop layer as a partial dielectric layer;
depositing a resistor metal layer on the partial dielectric layer; and
patterning and etching the resistor metal layer to form the metal resistor in the via zero interconnect layer.

13. The method of claim 12, further comprising:
depositing the dielectric material on the metal resistor and the partial dielectric layer to form the via zero interconnect layer; and
depositing a second etch stop layer on the via zero interconnect layer.

14. The method of claim 10, further comprising:
depositing an interlayer dielectric (ILD) material on the first BEOL interconnect layer; and
forming a second BEOL interconnect layer on the first BEOL interconnect layer.

15. An integrated circuit (IC), comprising:
a substrate including an active device having an active region;
a middle-of-line (MOL) interconnect layer having a contact merge (CM) layer on a trench contact coupled to the active region of the active device;
a plurality of back-end-of-line (BEOL) interconnect layers on the MOL interconnect layer; and
means for improving alternating current (AC) performance of the IC in a via zero interconnect layer between a first BEOL interconnect and the MOL interconnect layer, the AC performance improving means coupled to the active region through a first via zero on the CM layer, a second via zero on the AC performance improving means, and the first BEOL interconnect on the first via zero and the second via zero.

16. The IC of claim 15, in which a height of the first via zero is greater than a height of the second via zero.

17. The IC of claim 15, in which a height of the MOL interconnect layer is less than a height of the via zero interconnect layer.

18. The IC of claim 15, in which the via zero interconnect layer comprises a low-K dielectric material.

19. The IC of claim 15, further comprising:
a first etch stop layer between a front-end-of-line (FEOL) layer and the MOL interconnect layer; and
a second etch stop layer between the MOL interconnect layer and the via zero interconnect layer.

20. The IC of claim 15, in which the active device comprises a complementary metal oxide semiconductor (CMOS) transistor and the active region comprises a source/drain region.
